(19) United States
(12) Patent Application Publication
(10) Pub. No.: US 2025/0392801 A1
(43) Pub. Date: Dec. 25, 2025

(54) SEMICONDUCTOR PACKAGE, CAMERA MODULE, AND CAMERA

(71) Applicant: Samsung Electronics Co., Ltd., Suwon-si (KR)

(72) Inventor: Kosuke HAREYAMA, Yokohama (JP)

(73) Assignee: Samsung Electronics Co., Ltd., Suwon-si (KR)

(21) Appl. No.: 19/240,811

(22) Filed: Jun. 17, 2025

(30) Foreign Application Priority Data
Jun. 21, 2024 (JP) 2024-100148

(51) Int. Cl. H04N 23/54; H04N 23/52

(52) U.S. Cl. CPC H04N 23/54; H04N 23/52

(57) ABSTRACT

The technical idea of the inventive concepts provide a solid-state imaging device including a chip substrate, and a semiconductor device. A circuit board is at an outer peripheral portion of a first surface of the chip substrate, the first surface of the chip substrate configured to be a surface on which light is incident. The circuit board includes a first surface configured to be a surface on which light is incident, and a second surface that is opposite to the first surface of the circuit board. The semiconductor device is on the second surface of the circuit board.

### CROSS-REFERENCE TO RELATED APPLICATION

This application claims the benefit of Japanese Patent Application No. 2024-100148, filed on Jun. 21, 2024, in the Japanese Patent Office, the disclosure of which is incorporated herein in its entirety by reference.

### BACKGROUND

Example embodiments of the inventive concepts relate to a semiconductor package, a camera module including the semiconductor package, and a camera including the camera module.

Recently, demands have increased for miniaturization and thinness of camera modules mounted in electronic devices, such as smartphones and digital cameras.

In existing camera modules, a frame, electronic components, and the like may be mounted on the upper surface (a surface on which light is incident) of a circuit board and arranged around a complementary metal oxide semiconductor (CMOS) image sensor (CIS) that is a solid-state imaging device. Thus, the circuit board may have minimal area in which a semiconductor device, such as an image signal processor (ISP) or a semiconductor memory, is mountable. Accordingly, the existing camera modules may have a structure in which a solid-state imaging device is separately mounted from a semiconductor device on a mounting substrate (a motherboard).

Furthermore, in the existing structures, a flexible substrate, a connector, or the like for connecting the mounting substrate to the solid-state imaging device may be utilized, thereby causing an increase in manufacturing cost due to an increase in the number of components in a camera and an increase in a mounting area. In addition, in the existing structures, the solid-state imaging device and the semiconductor device may be mounted in separate positions, and thus, the distance between components may be increased, which may increase a transmission loss of an electrical signal.

### SUMMARY

Example embodiments of inventive concepts provide a semiconductor package, a camera module, and a camera capable of reducing the number of connection components for a solid-state imaging device and a semiconductor device with respect to a connection substrate, thereby reducing a transmission loss of an electrical signal between components and/or reducing a mounting area.

According to some example embodiments of the inventive concepts, there is provided a semiconductor package. The semiconductor package may include a solid-state imaging device including a chip substrate, a semiconductor device, and a circuit board at an outer peripheral portion of a first surface of the chip substrate, the first surface of the chip substrate configured to be a surface on which light is incident. A first surface of the circuit board is configured to be a surface on which light is incident, a second surface of the circuit board is opposite to the first surface of the circuit board, and the semiconductor device is on the second surface of the circuit board.

According to some example embodiments of the inventive concepts, there is provided a camera module. The camera module may include a semiconductor package, and an optical portion including a lens portion, wherein the semiconductor package comprises a solid-state imaging device including a chip substrate, a semiconductor device positioned in a lateral direction of the solid-state imaging device, a circuit board at an outer peripheral portion of a first surface of the chip substrate, the first surface of the chip substrate configured to be a surface on which light is incident, and a protective member including a transparent material covering a light receiving region of the solid-state imaging device. A first surface of the circuit board is configured to be a surface on which light is incident, a second surface of the circuit board is opposite to the first surface of the circuit board, the semiconductor device is on the second surface of the circuit board, the protective member is on the first surface of the circuit board, and the semiconductor package is beneath the lens portion.

According to some example embodiments of the inventive concepts, there is provided a camera. The camera may include a camera module and a heat-dissipating body, wherein the camera module comprises a semiconductor package and a lens portion, and the semiconductor package comprises a solid-state imaging device having a chip substrate, a semiconductor device positioned in a lateral direction of the solid-state imaging device, and a circuit board at an outer peripheral portion of a first surface of the chip substrate, the first surface of the chip substrate configured to be a surface on which light is incident. A first surface of the circuit board is configured to be a surface on which light is incident, and a second surface of the circuit board is opposite to the first surface of the circuit board, the semiconductor device is on the second surface of the circuit board, the heat-dissipating body is beneath the semiconductor package, and the solid-state imaging device and the semiconductor device are mounted in the semiconductor package of the camera module and are thermally connected to the heat-dissipating body through an adhesive layer having a thermal conductivity.

According to some example embodiments of the inventive concepts, a method of manufacturing a semiconductor package may include mounting an electronic component on a first surface of a circuit board, coating a window portion of the circuit board with an encapsulant, bonding a protective member to the circuit board, mounting a solid-state imaging device including a chip substrate to a second surface of the circuit board using a first flip-chip process, mounting an on-chip lens and an image sensor on the first surface of the circuit board, forming a first connection terminal connected to a first wiring of the circuit board, bonding the solid-state imaging device to the circuit board by an annular encapsulation portion, and forming an encapsulation space, mounting a semiconductor device to the second surface of the circuit board in a second flip-chip process, connecting a second connection terminal of the semiconductor device to a second wiring of the circuit board, coating a side surface of the semiconductor device and the second connection terminal of the semiconductor device with a resin to form an encapsulation resin layer, and performing a grinding process on the encapsulation resin layer, the second surface of the chip substrate, the solid-state imaging device, and the second surface of the semiconductor device.

According to some example embodiments of the inventive concepts, the method of manufacturing the semiconductor package may further include after performing the grinding process, the second surface of the chip substrate, the solid-state imaging device, and the second surface of the semiconductor device are exposed, or after performing the grinding process, the second surface of the chip substrate, and the solid-state imaging device, are exposed and at least a portion of the second surface of the semiconductor device is still covered by the encapsulation resin layer.

### BRIEF DESCRIPTION OF THE DRAWINGS

Some example embodiments of the inventive concepts will be more clearly understood from the following detailed description taken in conjunction with the accompanying drawings in which:

FIG. 1 is a cross-sectional view schematically illustrating a camera having a semiconductor package and a camera module, according to some example embodiments;

FIG. 2 is a perspective view schematically illustrating a first surface of a solid-state imaging device;

FIGS. 3A to 3H are cross-sectional views schematically illustrating a method of manufacturing a semiconductor package, according to some example embodiments;

FIG. 4 is a partially enlarged cross-sectional view of a camera having a semiconductor package and a camera module, according to some example embodiments; and

FIG. 5 is a partially enlarged cross-sectional view of a camera having a semiconductor package and a camera module, according to some example embodiments.

### DETAILED DESCRIPTION

Hereinafter, some example embodiments are described in detail with reference to the accompanying drawings. Like reference numerals in the drawings below denote like elements, and the sizes of components in the drawings may be exaggerated for clarity and convenience of description. Embodiments described below are only illustrative, and various modifications may be made from the embodiments.

Hereinafter, when it is described that a certain component is “on” or “above” another component, the certain component is directly on the other component in a contact manner or is above the other component in a contactless manner. Likewise, when it is described that a certain component is “beneath”, “below”, or “under” another component, the certain component is directly beneath the other component in a contact manner or is below or under the other component in a contactless manner.

An expression in the singular includes an expression in the plural unless they are clearly different from each other in context. In addition, when a certain part “includes” or “has” a certain component, this indicates that the part may further include another component instead of excluding another component unless there is different disclosure.

For steps forming the methods, if an order is not clearly disclosed or, if there is no disclosure opposed to the clear order, the steps can be performed in any order deemed proper. The methods are not necessarily limited to the disclosed order of the steps. The use of all illustrations or illustrative terms is simply to describe the technical idea, and the scope is not limited due to the illustrations or illustrative terms unless they are limited by claims.

In addition, when ordinal numerals, such as “first” and “second”, are used in the description below, the ordinal numerals are used for convenience unless the context clearly dictates otherwise, and do not indicate a specific sequence.

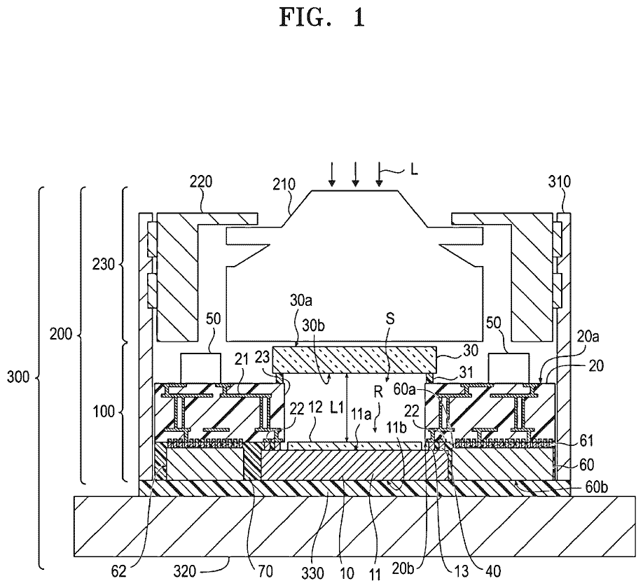

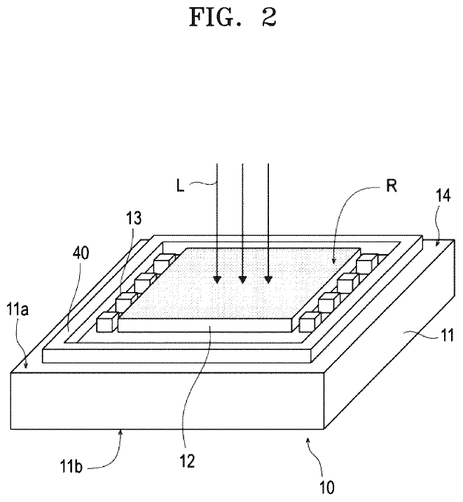

FIG. 1 is a cross-sectional view schematically illustrating a camera 300 having a semiconductor package 100 and a camera module 200, according to some example embodiments. FIG. 2 is a perspective view schematically illustrating a solid-state imaging device 10.

Referring to FIGS. 1 and 2, the camera 300 according to the technical idea of the inventive concepts may include the camera module 200. The camera module 200 may include the semiconductor package 100. The camera 300 may be mounted as an imaging portion of various kinds of electronic devices including portable terminals, such as a smartphone and a tablet terminal, and imaging devices, such as a digital still camera and a video camera. Incident light L irradiated on the camera 300 may be incident to the solid-state imaging device 10 of the semiconductor package 100 through an optical portion 230.

As shown in FIG. 1, the semiconductor package 100 may include the solid-state imaging device 10 including a complementary metal oxide semiconductor (CMOS) image sensor (CIS), a circuit board 20, a protective member 30, an annular encapsulation portion 40, an electronic component 50, a semiconductor device 60, and an encapsulation resin layer 70.

The solid-state imaging device 10 may have a chip substrate 11 formed of silicon. An integrated circuit (IC) circuit pattern and the like may be formed on a first surface 11a of the chip substrate 11, and the solid-state imaging device 10 may convert received light into an electrical signal and output the electrical signal as a pixel signal. The solid-state imaging device 10 has a light-receiving region R in which a plurality of pixels configured to convert incident light into an electrical signal are arranged horizontally and vertically in a column shape, and may include a CIS on which a color filter, a photodiode, a pixel circuit, and the like (not shown) are mounted in addition to an on-chip lens (microlens) 12. As shown in FIG. 2, the light-receiving region R may correspond to, for example, a forming region (a dot-hatch portion) of the on-chip lens 12.

The chip substrate 11 has the first surface 11a that is a surface on which light is incident and a second surface 11b that is opposite to the first surface 11a in the chip substrate 11. In FIG. 1, the first surface 11a of the chip substrate 11 may be defined as the upper surface of the chip substrate 11, and the second surface 11b of the chip substrate 11 may be defined as the lower surface of the chip substrate 11. The solid-state imaging device 10 may be disposed at an inner side of a second surface 20b of the circuit board 20 so as to be electrically connected to a wiring 21 via a first connection terminal 13 formed on the first surface 11a of the chip substrate 11.

The first connection terminal 13 including a solder bump or the like and electrically connected to the circuit board 20 may be formed at an outer side of the light-receiving region R (an outer side of the on-chip lens 12) on the first surface 11a of the chip substrate 11. The solid-state imaging device 10 may be disposed at an inner side of the semiconductor device 60 on the second surface 20b of the circuit board 20 so as to be electrically connected to the circuit board 20 via the first connection terminal 13. The first connection terminal 13 may be connected to an inner side of the second surface 20b of the circuit board 20.

The solid-state imaging device 10 may have the annular encapsulation portion 40 formed to surround the on-chip lens 12, disposed in the light-receiving region R and the first connection terminal 13 on the chip substrate 11.

The first connection terminal 13 and the annular encapsulation portion 40 may be formed on an outer peripheral portion 14 of the first surface 11a of the chip substrate 11. The outer peripheral portion 14 may be understood as a certain region from a portion positioned outside the light-receiving region R of the first surface 11a of the chip substrate 11 to the outer circumferential portion of the first surface 11a.

The thickness of the solid-state imaging device 10 in the vertical direction may be substantially the same as the thickness of the semiconductor device 60 in the vertical direction. However, example embodiments are not limited thereto. To this end, the second surface 11b of the chip substrate 11 may be ground to adjust the height of the solid-state imaging device 10. Herein, the wording “substantially the same as” may include not only a shape in which there is no thickness difference in the vertical direction (no distance difference to a heat-dissipating body 320) between the solid-state imaging device 10 and the semiconductor device 60 to be compared but also a shape in which, even though there is a thickness difference (a distance difference to the heat-dissipating body 320) therebetween, the thickness difference is 200 μm or less corresponding to thickness non-uniformity absorbable by an adhesive layer 330.

The circuit board 20 may include an interposer substrate (a relay substrate) and may be electrically connected to the solid-state imaging device 10, the electronic component 50, the semiconductor device 60, and the like via the wiring 21 formed inside the circuit board 20. The circuit board 20 may be formed in a rectangular frame shape having a window portion 23 at the center portion thereof such that light is incident on the light-receiving region R of the solid-state imaging device 10. The circuit board 20 may be disposed to cover the outer peripheral portion 14 of the solid-state imaging device 10.

The circuit board 20 may have a first surface 20a that is a surface on which light is incident and the second surface 20b that is opposite to the first surface 20a in the circuit board 20. In FIG. 1, the first surface 20a of the circuit board 20 may be defined as the upper surface of the circuit board 20, and the second surface 20b of the circuit board 20 may be defined as the lower surface of the circuit board 20.

The circuit board 20 may include a resin of which the linear expansion coefficient is 6 ppm/° C. or less in terms of relaxation improvement of stress due to a temperature change. The protective member 30 mounted on the circuit board 20 may include, for example, borosilicate glass (about 7 ppm/° C.) or blue glass (about 7 ppm/° C. to about 8 ppm/° C.) having an infrared (IR) cut function. The solid-state imaging device 10 mounted on the circuit board 20 may include silicon (about 4 ppm/° C.) as a material of the chip substrate 11. In general, because the solid-state imaging device 10 and the protective member 30 have a difference in the linear expansion coefficient therebetween, there may occur warpage in the circuit board 20 due to heat generation while operating the camera 300 and the like. However, because the linear expansion coefficient of the circuit board 20 according to some example embodiments is 6 ppm/° C. or less, which is between the linear expansion coefficient of the solid-state imaging device 10 and the linear expansion coefficient of the protective member 30, the influence of the linear expansion coefficient difference between the solid-state imaging device 10 and the protective member 30 may be alleviated to suppress the occurrence of warpage of the circuit board 20.

The circuit board 20 may include a connection portion 22 that is metallic to fix the annular encapsulation portion 40. The connection portion 22 may merely function to fix the annular encapsulation portion 40 or may function as an electrode electrically connected to another component.

The protective member 30 may include a transparent material, for example, a glass material, a resin material, such as polyimide, or the like. However, example embodiments are not limited thereto. The protective member 30 may include IR cut protection glass (borosilicate glass or blue glass) or an IR cut filter. The planar size of the protective member 30 may be greater than or equal to the planar size of the light-receiving region R of the chip substrate 11.

The protective member 30 may have a first surface 30a that is a surface on which light is incident and a second surface 30b that is opposite to the first surface 30a in the protective member 30. In FIG. 1, the first surface 30a of the protective member 30 may be defined as the upper surface of the protective member 30, and the second surface 30b of the protective member 30 may be defined as the lower surface of the protective member 30. Light having passed through the protective member 30 may pass through the window portion 23 of the circuit board 20 and then be incident on the light-receiving region R of the solid-state imaging device 10.

As shown in FIG. 1, the protective member 30 may be bonded to the circuit board 20 by a bonding portion 31 including an encapsulant formed around the second surface 30b in a state in which the second surface 30b faces the window portion 23 of the circuit board 20.

A distance A1 from the surface of the on-chip lens 12 of the solid-state imaging device 10 to the second surface 30b of the protective member 30 is preferably 0.6 mm or more. Accordingly, in the semiconductor package 100, a flare component reflected from the protective member 30 disposed on the solid-state imaging device 10 and incident again to the solid-state imaging device 10 may be decreased.

As shown in FIG. 2, the annular encapsulation portion 40 may be formed on the first surface 11a of the chip substrate 11 to surround the on-chip lens 12, disposed in the light-receiving region R, and the first connection terminal 13 on the chip substrate 11. The annular encapsulation portion 40 may be formed of solder on the outer peripheral portion 14 of the first surface 11a. As shown in FIG. 1, the semiconductor package 100 may have an encapsulation space S airtight-encapsulated by the protective member 30 disposed on the circuit board 20 and the annular encapsulation portion 40 formed below the circuit board 20. The on-chip lens 12, the first connection terminal 13, and the like may be airtight-encapsulated in the encapsulation space S.

The annular encapsulation portion 40 may be formed using a known solder formation method at the same time as a process of forming the first connection terminal 13 on the chip substrate 11. As an example of the formation method, the annular encapsulation portion 40 may be formed by coating the first surface 11a of the chip substrate 11 with a photosensitive insulating layer made of (but not limited to) an epoxy resin or the like, removing an unnecessary portion of the photosensitive insulating layer through a known photolithography process, forming a metal barrier layer through a known deposition process, such as sputtering or chemical vapor deposition (CVD), then performing a masking process using a resist to form the first connection terminal 13 and the annular encapsulation portion 40, followed by solder formation and plating (copper (Cu)/tin (Sn)/silver (Ag)), and removing an unnecessary metal barrier layer and the resist. The chip substrate 11 may be formed by removing the metal barrier layer and the resist. In addition, the thickness of the solid-state imaging device 10 on which the first connection terminal 13 and the annular encapsulation portion 40 are formed may be adjusted through a process of grinding at least a portion of the second surface 11b of the chip substrate 11 by grinding (gliding). Once the thickness of the solid-state imaging device 10 is adjusted through a grinding process or the like, the second surface 11b of the chip substrate 11 may have a ground surface. The ground surface may have different surface properties such as roughness or uniformity.

The electronic component 50 is a passive device, such as a resistor or a capacitor, and may constitute a peripheral circuit of the semiconductor package 100 or the camera module 200. The electronic component 50 may be mounted on the first surface 20a of the circuit board 20 and electrically connected to the solid-state imaging device 10 or the semiconductor device 60 via the wiring 21.

The semiconductor device 60 may be a semiconductor component other than the solid-state imaging device 10 in the semiconductor package 100. The semiconductor device 60 may include one or more devices selected from among a semiconductor memory, an image signal processor (ISP), a graphics processing unit (GPU), and the like.

The semiconductor device 60 may have a first surface 60a that is a surface on which light is incident and a second surface 60b that is opposite to the first surface 60a in the semiconductor device 60. In FIG. 1, the first surface 60a of the semiconductor device 60 may be defined as the upper surface of the semiconductor device 60, and the second surface 60b of the semiconductor device 60 may be defined as the lower surface of the semiconductor device 60. The semiconductor device 60 may be electrically connected to the wiring 21 via a second connection terminal 61 formed on the first surface 60a. The semiconductor device 60 may be disposed at an outer side of the solid-state imaging device 10 on the second surface 20b of the circuit board 20.

According to some example embodiments, when a plurality of semiconductor devices 60 having different chip heights are mounted on the circuit board 20, the chip height difference between every two semiconductor devices 60 is preferably 200 μm or less. Accordingly, when the camera module 200 is disposed on the heat-dissipating body 320 of the camera 300, the height difference between every two semiconductor devices 60 of the semiconductor package 100 may be offset by the adhesive layer 330. According to some example embodiments, at least a portion of the second surface 60b of at least one semiconductor device 60 may be ground such that the chip heights of the plurality of semiconductor devices 60 mounted on the circuit board 20 are substantially the same as each other.

The encapsulation resin layer 70 may include a thermosetting resin, such as an epoxy resin, having an insulating property and cover a side surface 62 and the second connection terminal 61 of the semiconductor device 60.

It is preferable to appropriately select a resin to be used for the encapsulation resin layer 70 such that the linear expansion coefficient of the encapsulation resin layer 70 is about 3 ppm/° C. to about 25 ppm/° C. inclusive in terms of suppression of strain (warpage of a device surface and the like) of the semiconductor device 60 due to a temperature change. With respect to the linear expansion coefficient of the encapsulation resin layer 70, 3 ppm/° C. that is the lower limit of the numerical value range may approximate the linear expansion coefficient of silicon that is a chip material of the semiconductor device 60, and 25 ppm/° C. that is the upper limit of the numerical value range may approximate the linear expansion coefficient of a resin, such as an epoxy resin, used for the circuit board 20. Accordingly, when the linear expansion coefficient of the encapsulation resin layer 70 is set within the linear expansion coefficient numerical value range described above, strain of the semiconductor device 60 due to a temperature change or the like may be suppressed to be reduced and/or minimized.

The encapsulation resin layer 70 may cover the second surface 60b of the semiconductor device 60 with a lower chip height such that the height positions of the plurality of semiconductor devices 60 from the circuit board 20 are substantially the same as each other when the chip heights (thickness-direction lengths) of the plurality of semiconductor devices 60 mounted on the circuit board 20 are different from each other.

The encapsulation resin layer 70 may be integrally formed of a homogeneous resin or layered and formed using different materials, such as an underfill material, including (but not limited to) an epoxy resin or the like as a main material in a region, e.g., the surroundings of the first connection terminal 13, in which it is difficult to adopt a resin.

As described above, as shown in FIG. 1, in the semiconductor package 100 according to the example embodiments of the inventive concepts, the electronic component 50 may be mounted on the first surface 20a of the circuit board 20, and the solid-state imaging device 10 and the semiconductor device 60 may be mounted on the second surface 20b of the circuit board 20. In a semiconductor module mounted in an existing camera module because a mounting space for a semiconductor device, such as an ISP, cannot be ensured on a circuit board on which a solid-state imaging device is mounted, the semiconductor device may be required to be separately mounted on a mounting substrate at a separate position from the solid-state imaging device. Furthermore, the planar size of the solid-state imaging device 10 tends to gradually increase for the purpose of higher precision of a captured image, and accordingly, the size of the circuit board 20 disposed around the solid-state imaging device 10 also increases. However, in the semiconductor package 100 according to the technical idea of the inventive concepts, a marginal space according to an increase in the size of the circuit board 20 may effectively be used to reduce the mounting area of a module, and the mounting distances among the solid-state imaging device 10, the electronic component 50, and the semiconductor device 60 may be reduced without using a connection component, such as a flexible substrate, which may reduce signal transmission loss significantly.

The camera module 200 may include the semiconductor package 100 described above and the optical portion 230. In the camera module 200, the semiconductor package 100 may be disposed beneath the optical portion 230 (at an opposite side to a light incident side of the optical portion 230), as shown in FIG. 1.

The optical portion 230 may concentrate light from a subject and irradiate the light on the solid-state imaging device 10. The optical portion 230 may include a lens portion 210 and an actuator 220.

The lens portion 210 may have a lens group including of a plurality of lenses (not shown) and form a subject image on the light-receiving region R of the solid-state imaging device 10. The actuator 220 may be fixed to a casing 310 of the camera 300 and drive certain lenses included in the lens group, for example, in the direction facing the solid-state imaging device 10 (in the up/down direction in FIG. 1) and a horizontal direction (in the left/right direction and forward/backward direction in FIG. 1). Accordingly, at least one of an autofocus function and an image stabilization function may be realized.

In some example embodiments, the actuator 220 may be a simple lens holder having neither the autofocus function nor the image stabilization function. In this case, the autofocus function and the image stabilization function may be realized by image processing and the like.

The camera 300 may include the camera module 200 described above, the casing 310, the heat-dissipating body 320, and the adhesive layer 330.

The camera module 200 may transfer heat to the heat-dissipating body 320 through the adhesive layer 330 having sufficient thermal conductivity. Accordingly, heat generated by components of the semiconductor package 100, in particular, the solid-state imaging device 10 and the semiconductor device 60 having a high heating temperature during an operation thereof, may be effectively dissipated.

The heat-dissipating body 320 is a thermally conductive member, such as a graphite sheet, a metal component, or a vapor chamber, and may have a thermal conductivity greater than or equal to the thermal conductivity (168 W/mK) of silicon in terms of a heat-dissipation property. In some example embodiments, the heat-dissipating body 320 preferably uses a member having a thermal conductivity of 150 W/mK or more so as to obtain a sufficient heat-dissipating effect.

The adhesive layer 330 is a thermally conductive adhesive and may be coated on the bottom of the semiconductor package 100. The adhesive layer 330 may be coated on the second surface 11b of the chip substrate 11 of the solid-state imaging device 10 and the second surface 60b of the semiconductor device 60 when the solid-state imaging device 10 and the semiconductor device 60 are positioned at the bottom of the semiconductor package 100, and coated on the surface of the encapsulation resin layer 70 when the solid-state imaging device 10 and the semiconductor device 60 are covered by the encapsulation resin layer 70. The adhesive layer 330 preferably uses an adhesive of which the thermal conductivity is 3 W/mK or more in terms of a heat-dissipation property.

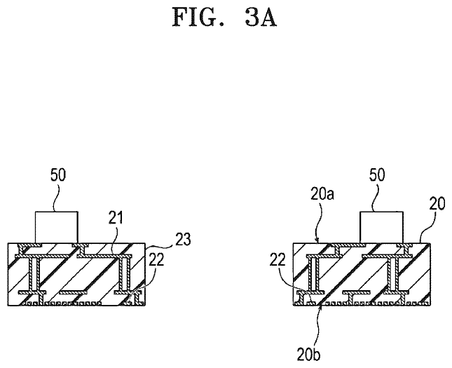

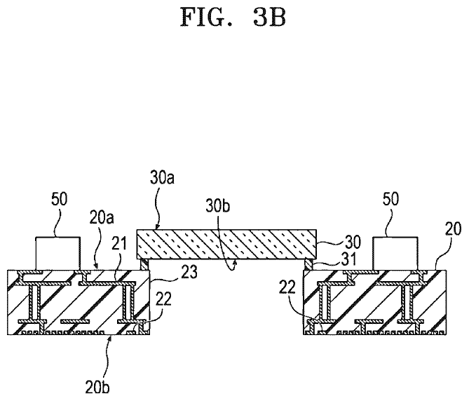

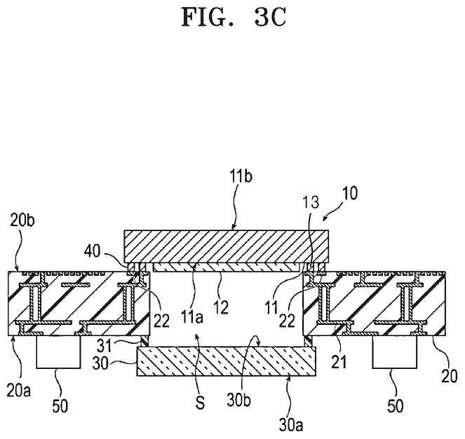

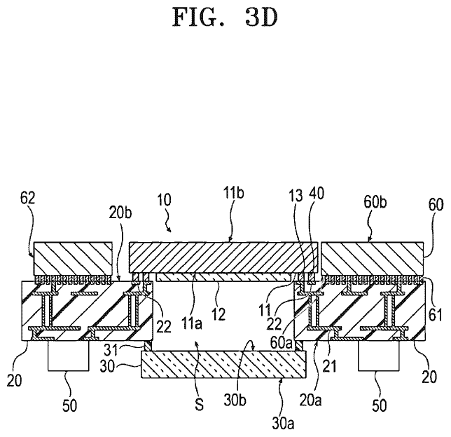

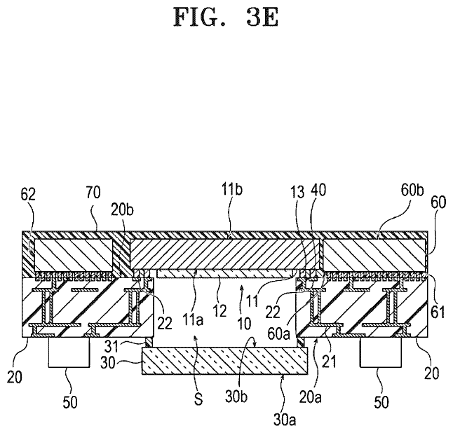

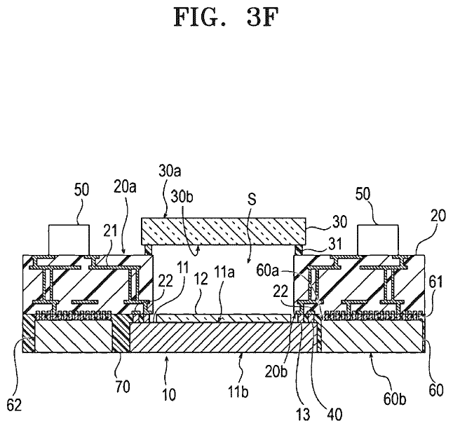

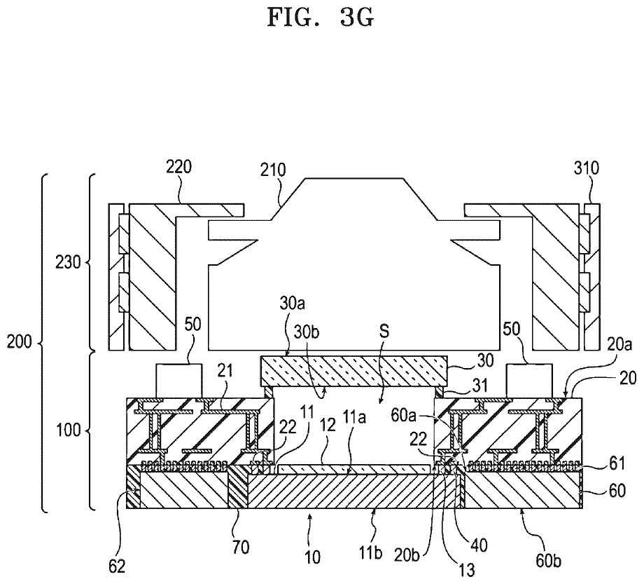

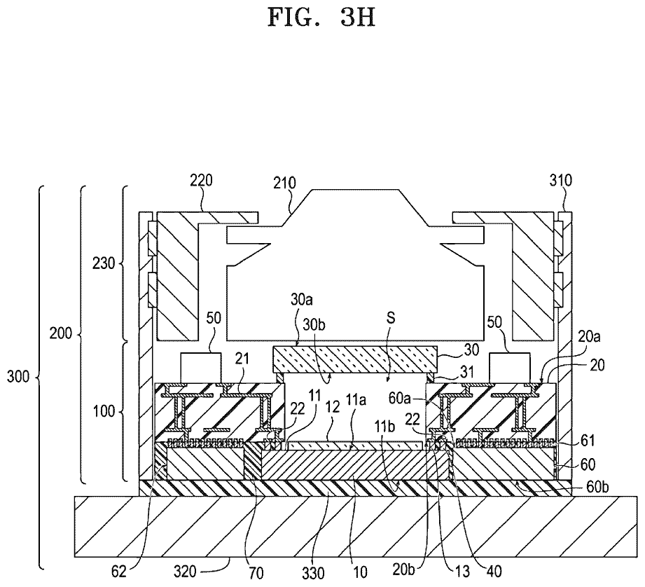

FIGS. 3A to 3H are cross-sectional views schematically illustrating a method of manufacturing a semiconductor package, according to some example embodiments. In addition, methods of manufacturing the semiconductor package 100, the camera module 200, and the camera 300, according to some example embodiments, may be described through processes 1 to 8 below. The method of manufacturing the semiconductor package 100 includes the processes 1 to 6 below, the method of manufacturing the camera module 200 includes the process 7, and the method of manufacturing the camera 300 includes the process 8.

Referring to FIGS. 3A to 3H, in the process 1, the electronic component 50 is mounted on the first surface 20a of the circuit board 20, as shown in FIG. 3A. The types, the mounting number, the mounting positions, and the like of electronic components 50 mounted on the circuit board 20 may be set appropriately according to the specification and the like of the camera module 200. In the process 2, as shown in FIG. 3B, an encapsulant is coated around the window portion 23 of the circuit board 20, and the protective member 30 is bonded to the circuit board 20 such that the second surface 30b of the protective member 30 faces the window portion 23. In the process 2, hardening is performed on the encapsulant to form the bonding portion 31.

In the process 3, as shown in FIG. 3C, the solid-state imaging device 10 is flip-chip-mounted on the second surface 20b of the circuit board 20. On the first surface 11a of the chip substrate 11 of the solid-state imaging device 10, the on-chip lens 12 and each component constituting an image sensor besides the on-chip lens 12 may be mounted, and the first connection terminal 13 and the annular encapsulation portion 40 may also be formed. In the process 3, the first connection terminal 13 of the solid-state imaging device 10 may be connected to the wiring 21 of the circuit board 20, and in addition, the solid-state imaging device 10 may be bonded to the circuit board 20 by the annular encapsulation portion 40 to form the encapsulation space S.

In the process 4, as shown in FIG. 3D, the semiconductor device 60 is flip-chip-mounted on the second surface 20b of the circuit board 20. In the process 4, the second connection terminal 61 of the semiconductor device 60 may be connected to the wiring 21 of the circuit board 20.

In the process 5, as shown in FIG. 3E, the encapsulation resin layer 70 is formed. The encapsulation resin layer 70 may be formed by coating a resin, such as an epoxy resin, to cover the side surface 62 and the second connection terminal 61 of the semiconductor device 60.

In the process 6, as shown in FIG. 3F, the encapsulation resin layer 70, the second surface 11b of the chip substrate 11 of the solid-state imaging device 10, and the second surface 60b of the semiconductor device 60 are ground such that the chip substrate 11 of the solid-state imaging device 10 and the semiconductor device 60 have certain thicknesses. Accordingly, the second surface 11b of the chip substrate 11 of the solid-state imaging device 10 and the second surface 60b of the semiconductor device 60 are exposed. In addition, in the process 6, a grinding process may be performed such that both the second surface 11b of the chip substrate 11 of the solid-state imaging device 10 and the second surface 60b of the semiconductor device 60 are exposed, as shown in FIG. 3F, or grinding may be performed such that at least a portion of the second surface 60b of the semiconductor device 60 is covered by the encapsulation resin layer 70. The semiconductor package 100 is completed through the processes 1 to 6.

In the process 7, as shown in FIG. 3G, the semiconductor package 100 manufactured in the process 6 may be assembled with the optical portion 230 to manufacture the camera module 200. The optical portion 230 is disposed on the semiconductor package 100, that is, at a light incident side.

In the process 8, as shown in FIG. 3H, the camera module 200 manufactured in the process 7 may be disposed on the heat-dissipating body 320 to manufacture the camera 300. The heat-dissipating body 320 is provided on the lower surface of the camera module 200 through the adhesive layer 330 having a sufficient thermal conductivity so as to dissipate heat generated from the second surface 11b of the chip substrate 11 of the solid-state imaging device 10 and the second surface 60b of the semiconductor device 60. In addition, the camera 300 may also be manufactured through assembly processing of another component or the like besides providing the camera module 200 on the heat-dissipating body 320.

In addition, each manufacturing method described above may include a process of performing processing other than the processes 1 to 8. In addition, the carry-out order of the processes 1 to 8 may be appropriately changed when the features and functions of the semiconductor package 100, the camera module 200, and the camera 300 to be manufactured are guaranteed.

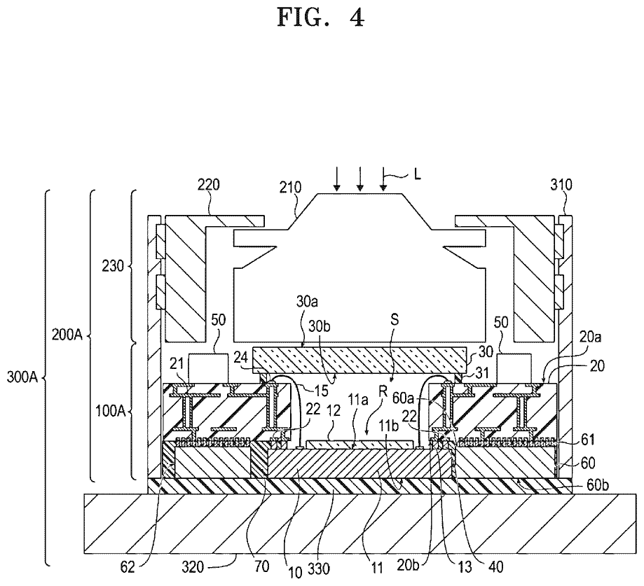

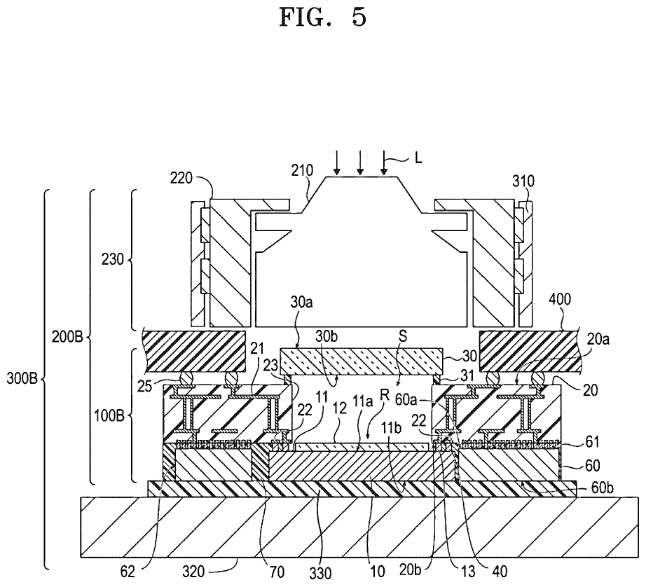

FIG. 4 is a partially enlarged cross-sectional view of a camera 300A having a semiconductor package 100A and a camera module 200A, according to some example embodiments. FIG. 5 is a partially enlarged cross-sectional view of a camera 300B having a semiconductor package 100B and a camera module 200B, according to some example embodiments. Hereinafter, the description made with reference to FIGS. 1 to 3H is omitted. In addition, hereinafter, modified examples of the inventive concepts are described. In the modified examples described below, like reference numerals denote like elements, and thus, a description thereof is omitted. In addition, matters not particularly mentioned in each modified example may be configured as in the embodiments described above. Additionally, each modified example may be carried out in combination with another aspect by appropriately selecting necessary features among the features in each modified example without departing from the spirit and scope of the inventive concepts.

First, the semiconductor package 100A, the camera module 200A, and the camera 300A according to modified example 1 of the inventive concepts are described with reference to FIG. 4.

The camera 300A of the modified example 1 may include the semiconductor package 100A and the camera module 200A, as shown in FIG. 4.

A third connection terminal 24 electrically connected to the solid-state imaging device 10 may be formed on the first surface 20a of the circuit board 20. The solid-state imaging device 10 may be electrically connected to the third connection terminal 24 by a wire bonding through a wire 15 formed of, for example, gold, aluminum, Cu, or the like. However, example embodiments are not limited thereto.

The semiconductor package 100A of the modified example 1 differs from the semiconductor package 100 described above in that a connection form of the solid-state imaging device 10 to the circuit board 20 is changed from the bottom of the circuit board 20 to the top of the circuit board 20. By doing this, the semiconductor package 100 or 100A may be selected to be appropriate for the shape of the circuit board 20 designed according to the specification of the camera 300 or 300A.

The semiconductor package 100B, the camera module 200B, and the camera 300B according to modified example 2 of the inventive concepts are described with reference to FIG. 5.

In the camera 300B of the modified example 2, as shown in FIG. 5, a fourth connection terminal 25 electrically connected to a mounting substrate 400 is formed on the first surface 20a of the circuit board 20. The fourth connection terminal 25 may be formed on the first surface 20a of the circuit board 20 and at an outer side of the protective member 30. The mounting substrate 400 is connected to an external substrate not shown in FIG. 5. The mounting substrate 400 may function as a wiring layer configured to exchange a control signal between the external substrate and the solid-state imaging device 10 or the semiconductor device 60 constituting the semiconductor package 100B. The control signal may include an electrical signal for supplying power to the solid-state imaging device 10 or the semiconductor device 60, a driving signal for performing various kinds of driving controls, and the like.

In the semiconductor package 100B, it is preferable that the difference between the linear expansion coefficient of the circuit board 20 and the linear expansion coefficient of the mounting substrate 400 is 4 ppm/° C. or less in terms of stress alleviation. Accordingly, the difference between the linear expansion coefficient of the circuit board 20 and the linear expansion coefficient of the mounting substrate 400 may be reduced, and through this, both the improvement of solder connection reliability and/or the reduction of warpage and the like of the camera module 200B and the solid-state imaging device 10 may be achieved.

In the camera module 200B, the size of the optical portion 230 may be appropriately set according to the specifications of the protective member 30 and the mounting substrate 400. The specifications of the protective member 30 and the mounting substrate 400 may be determined based on the size, the arrangement position, and the like of each member. The optical portion 230 of the camera module 200B may be miniaturized in a form without interfering with the protective member 30. In the same meaning, the optical portion 230 may be provided with a size which does not interfere with the protective member 30. In the camera module 200B, as shown in FIG. 5, the length of the optical portion 230 in the width direction thereof (the length of the optical portion 230 in the direction perpendicular to the thickness direction of the lens portion 210) may be less than the length of the circuit board 20 in the width direction thereof (the length of the circuit board 20 in the direction perpendicular to the thickness direction of the circuit board 20). Accordingly, high-precision mounting of the camera module 200B may be performed. Additionally, in the camera module 200B, the optical portion 230 may be enlarged within an allowable range by the mounting substrate 400.

In the semiconductor package 100B of the modified example 2, because the fourth connection terminal 25 is formed on the first surface 20a of the circuit board 20 and at an outer side of the protective member 30, when the camera module 200B is viewed from the top of the mounting substrate 400 connected to the fourth connection terminal 25, the mounting area of the optical portion 230 may be substantially the same as the imaging area of the solid-state imaging device 10, and this may contribute to high-precision mounting of the camera module 200B. In addition, the size of the optical portion 230 of the camera module 200B may be appropriately set according to the specifications of the protective member 30 and the mounting substrate 400. For example, the optical portion 230 may be miniaturized in a form without interfering with the protective member 30 to implement the high-precision mounting of the camera module 200B. Herein, the form without interfering with the protective member 30 may be understood as a form in non-contact with the protective member 30.

As described above, in the semiconductor package 100, 100A, or 100B according to some example embodiments of the inventive concepts, the solid-state imaging device 10 having the chip substrate 11 and the semiconductor device 60 are included, the circuit board 20 is disposed at an outer peripheral portion of the first surface 11a, which is a surface on which light is incident, of the chip substrate 11, the circuit board 20 has the first surface 20a, which is a surface on which light is incident, and the second surface 20b that is opposite to the first surface 20a in the circuit board 20, and the semiconductor device 60 is disposed on the second surface 20b of the circuit board 20.

For the semiconductor package 100, 100A, or 100B, because the solid-state imaging device 10 and the semiconductor device 60 are disposed on the second surface 20b of the circuit board 20, a mounting area in a product, such as a smartphone, may be reduced, and in addition, the number of connection components, such as a flexible substrate, may be reduced. In addition, because the arrangement position of the solid-state imaging device 10 is close to the arrangement position of the semiconductor device 60, transmission loss of an electrical signal between components may be reduced.

The camera module 200, 200A, or 200B according to some example embodiments of the inventive concepts includes the semiconductor package 100, 100A, or 100B and the optical portion 230 including the lens portion 210, and the semiconductor package 100, 100A, or 100B is disposed beneath the lens portion 210.

By this configuration, for the camera module 200, 200A, or 200, a mounting area in a product, such as a smartphone, may be reduced, and/or the number of connection components, such as a flexible substrate, may be reduced.

The camera 300, 300A, or 300B according to the inventive concepts includes the camera module 200, 200A, or 200B and the heat-dissipating body 320, and the solid-state imaging device 10 and the semiconductor device 60 mounted in the semiconductor package 100, 100A, or 100B of the camera module 200, 200A, or 200B are thermally connected to the heat-dissipating body 320 through the adhesive layer 330 having sufficient thermal conductivity.

By this configuration, the camera 300, 300A, or 300B may effectively dissipate heat from the solid-state imaging device 10 and/or the semiconductor device 60, which generate heat during an operation of the camera 300, 300A, or 300B.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the inventive concepts have been particularly shown and described with reference to example embodiments thereof, it will be understood that various changes in form and details may be made therein without departing from the spirit and scope of the following claims.

What is claimed is:

1. A semiconductor package comprising:
a solid-state imaging device including a chip substrate;
a semiconductor device; and
a circuit board at an outer peripheral portion of a first surface of the chip substrate, the first surface of the chip substrate configured to be a surface on which light is incident,
wherein
a first surface of the circuit board is configured to be a surface on which light is incident,
a second surface of the circuit board is opposite to the first surface of the circuit board, and
the semiconductor device is on the second surface of the circuit board.

2. The semiconductor package of claim 1, further comprising:
a protective member on the first surface of the circuit board covering at least a portion of a light-receiving region of the solid-state imaging device,
wherein the protective member includes a transparent material.

3. The semiconductor package of claim 1, further comprising:
a first connection terminal electrically connected to the circuit board on the first surface of the chip substrate of the solid-state imaging device; and
an annular encapsulation portion surrounding the first connection terminal and a light-receiving region of the solid-state imaging device on the first surface of the chip substrate and at an outer side of the first connection terminal.

4. The semiconductor package of claim 1, further comprising:
a second connection terminal on a first surface of the semiconductor device, the second connection terminal being electrically connected to the circuit board, and
an encapsulation resin layer covering a side surface of the semiconductor device and the second connection terminal.

5. The semiconductor package of claim 1, further comprising:
the semiconductor device including a plurality of semiconductor devices having different heights on the second surface of the circuit board; and
an encapsulation resin layer on a second surface of at least one of the plurality of semiconductor devices.

6. The semiconductor package of claim 5, wherein a difference between the heights of the plurality of semiconductor devices is 200 μm or less.

7. The semiconductor package of claim 1, further comprising:
the semiconductor device including a plurality of semiconductor devices, each having a same height, on the second surface of the circuit board,
wherein a second surface of at least one of the plurality of semiconductor devices includes a ground surface.

8. The semiconductor package of claim 1, further comprising:
a third connection terminal electrically connected to the solid-state imaging device on the first surface of the circuit board; and
a wire bonding electrically connecting the solid-state imaging device to the third connection terminal.

9. The semiconductor package of claim 1, further comprising:
a first connection terminal electrically connected to the circuit board on a first surface of the solid-state imaging device; and
a second connection terminal electrically connected to the circuit board on a first surface of the semiconductor device,
wherein
the first connection terminal is connected to the circuit board at an inner side of the second surface of the circuit board, and
the second connection terminal is connected to the circuit board at an outer side of the second surface of the circuit board.

10. The semiconductor package of claim 1, wherein the semiconductor device includes at least one component comprising a semiconductor memory, an image signal processor (ISP), or a graphics processing unit (GPU).

11. The semiconductor package of claim 2, further comprising:
an on-chip lens on the solid-state imaging device in the light-receiving region,
wherein a distance between a surface of the on-chip lens and a second surface of the protective member is 0.6 mm or more.

12. The semiconductor package of claim 2, wherein a linear expansion coefficient of the circuit board is 6 ppm/° C. or less.

13. The semiconductor package of claim 2, further comprising:
a fourth connection terminal electrically connected to a mounting substrate at an outer side of the protective member.

14. The semiconductor package of claim 13, wherein a difference between a linear expansion coefficient of the circuit board and a linear expansion coefficient of the mounting substrate is 4 ppm/° C. or less.

15. A camera module comprising a semiconductor package, and an optical portion including a lens portion, wherein the semiconductor package comprises:
a solid-state imaging device including a chip substrate;
a semiconductor device positioned in a lateral direction of the solid-state imaging device;
a circuit board at an outer peripheral portion of a first surface of the chip substrate, the first surface of the chip substrate configured to be a surface on which light is incident; and
a protective member including a transparent material covering a light receiving region of the solid-state imaging device,
wherein
a first surface of the circuit board is configured to be a surface on which light is incident,
a second surface of the circuit board is opposite to the first surface of the circuit board,
the semiconductor device is on the second surface of the circuit board,
the protective member is on the first surface of the circuit board, and
the semiconductor package is beneath the lens portion.

16. The camera module of claim 15, wherein the optical portion is not in contact with the protective member.

17. The camera module of claim 16, wherein a length of the optical portion in a width direction is less than a length of the circuit board in the width direction.

18. A camera comprising a camera module and a heat-dissipating body, wherein the camera module comprises a semiconductor package and a lens portion, and the semiconductor package comprises:
a solid-state imaging device having a chip substrate;
a semiconductor device positioned in a lateral direction of the solid-state imaging device; and
a circuit board at an outer peripheral portion of a first surface of the chip substrate, the first surface of the chip substrate configured to be a surface on which light is incident,
wherein
a first surface of the circuit board is configured to be a surface on which light is incident, and
a second surface of the circuit board is opposite to the first surface of the circuit board,
the semiconductor device is on the second surface of the circuit board,
the heat-dissipating body is beneath the semiconductor package, and
the solid-state imaging device and the semiconductor device are mounted in the semiconductor package of the camera module and are thermally connected to the heat-dissipating body through an adhesive layer having a thermal conductivity.

19. The camera of claim 18, wherein a thermal conductivity of the heat-dissipating body is 150 W/mK or more.

20. The camera of claim 18, wherein the thermal conductivity of the adhesive layer is 3 W/mK or more.
